(19) United States
(12) Patent Application Publication
(10) Pub. No.: US 2025/0320157 A1
(43) Pub. Date: Oct. 16, 2025

(54) HYDRAULICALLY CURABLE INORGANIC CEMENT COMPOSITION

(71) Applicant: Heraeus Electronics GmbH & Co. KG, Hanau (DE)

(72) Inventors: Markus SCHEIBEL, Hanau (DE); Tamara ALBERT, Hanau (DE); Nadja PELSHAW, Hanau (DE); Frederik ROTH, Hanau (DE); Gerd SCHULZ, Hanau (DE)

(21) Appl. No.: 18/861,057

(22) PCT Filed: Apr. 18, 2023
(86) PCT No.: PCT/EP2023/059949

§ 371 Date: Oct. 28, 2024

(30) Foreign Application Priority Data
May 2, 2022 (EP) 22171074.2

(51) Int. Cl. C04B 14/42; C04B 9/00; C04B 28/10; C04B 111/00

(52) U.S. Cl. CPC C04B 14/42; C04B 9/00; C04B 28/105; C04B 2111/00482

(57) ABSTRACT

A hydraulically curable inorganic cement composition comprising uncoated comminuted glass fibres made of low-alkali-oxide or alkali oxide-free glass and/or uncoated comminuted ceramic fibres made of low-alkali-oxide or alkali oxide-free ceramic.

The invention relates to a hydraulically curable inorganic cement composition from which an aqueous, hydraulically curable inorganic cement preparation can be produced by mixing with water. The aqueous, hydraulically curable inorganic cement preparation can be used to produce a hydraulically cured inorganic cement composition, in particular in the form of an encapsulation of an electronic component.

The term “hydraulic curing” as used herein comprises hardening in the presence of water or after the addition of water.

A distinction is made here between hydraulically curable inorganic cement composition, aqueous, hydraulically curable inorganic cement preparation and hydraulically cured inorganic cement composition. An aqueous, hydraulically curable inorganic cement preparation, particularly in the form of a viscoelastic, for example pasty or flowable compound, also referred to as “cement paste or cement glue,” can be produced from a hydraulically curable inorganic cement composition by mixing it with water. An aqueous, hydraulically curable inorganic cement preparation, in turn, can, after its application, cure and dry hydraulically to form a hydraulically cured inorganic cement composition in the form of a hard solid. This hard solid is also called “cement stone.” Such a hydraulically cured inorganic cement composition is substantially water-insoluble, that is, substantially or completely water-insoluble.

The term “electronic component” as used herein comprises, in addition to passive electronic components, in particular semiconductor modules and, among the latter, in particular electronic assemblies.

Semiconductor modules are understood here to mean electronic assemblies comprising at least one substrate (as a circuit carrier), at least one semiconductor component (semiconductor) and optionally at least one passive electronic component. The at least one semiconductor component can itself already be partially or completely pre-encapsulated, for example with an epoxy resin-based encapsulation.

The term “electronic assembly” is used herein. An electronic assembly in the context of the present invention comprises at least one substrate and at least one electronic component mechanically and electrically connected thereto. The mechanical and electrical connection can be an electrically conductive soldered, sintered and/or adhesive connection. Furthermore, such an electronic assembly can comprise elements serving for an electrical connection, such as bonding ribbons, bonding wires, clips, spacers and/or foils. Examples of framed or frameless electronic assemblies comprise discrete components such as so-called power discretes, power modules, voltage converters and certain sensors.

Examples of substrates comprise IMS substrates (insulated metal substrates), metal ceramic substrates such as AMB substrates (active metal brazed substrates), DCB substrates (direct copper bonded substrates), ceramic substrates, PCBs (printed circuit boards) and lead frames.

Electronic components can be divided into active and passive electronic components.

Examples of active electronic components comprise diodes, LEDs (light emitting diodes), dies (semiconductor chips), IGBTs (insulated-gate bipolar transistors), ICs (integrated circuits) and MOSFETs (metal-oxide-semiconductor field-effect transistors).

Examples of passive electronic components comprise base plates, heat sinks, connectors, resistors, capacitors, inductors, antennae, transformers, throttles, coils and sensors that do not constitute electronic assemblies.

The object of the invention was to provide a hydraulically curable inorganic cement composition comprising inorganic fibers, from which aqueous cement encapsulation compounds can be produced for producing encapsulations for electronic components. In addition to the reduced tendency to form cracks thanks to the inorganic fibers, the encapsulations shall be characterized by a high electrical insulation effect.

Hydraulically curable inorganic cement compositions comprising inorganic fibers or glass fibers are disclosed, for example, in EP 1 044 942 A1, WO 2015/067441 A1 and WO 2015/193035 A1.

It has been shown that the object can be achieved by providing a hydraulically curable inorganic cement composition comprising uncoated comminuted glass fibers made of low-alkali-oxide or alkali oxide-free glass and/or uncoated comminuted ceramic fibers made of low-alkali-oxide or alkali oxide-free ceramic.

The term “alkali oxide” as used herein refers in particular to the alkali metal oxides commonly used in the glass sector, namely lithium oxide, sodium oxide and potassium oxide.

The uncoated comminuted glass fibers made of low-alkali-oxide or alkali oxide-free glass are in particular those made of glass comprising <5 wt. %, preferably <2 wt. %, particularly preferably <1 wt. % alkali oxide.

It is substantial to the invention that the glass of the uncoated comminuted glass fibers is low in alkali oxide or free of alkali oxide, and in particular comprises <5 wt. %, preferably <2 wt. %, particularly preferably <1 wt. % alkali oxide. These may be quartz glass fibers. Preferably, the fibers are made of borosilicate glass, aluminosilicate glass or aluminum borosilicate glass, each with a correspondingly low or absent alkali oxide content.

It is also substantial to the invention that the glass fibers are uncoated.

The uncoated comminuted glass fibers can have a number-average fiber length, for example, in the range of 20 to 1000 μm, preferably 40 to 600 μm, in particular 40 to 300 μm, each with a diameter, for example, in the range of 5 to 50 μm, preferably 10 to 20 μm.

The number-averaged fiber length is mentioned several times herein. This can be determined, for example, using the FASEP® ECO System from IDM Systems, Helga Mayr, 64297 Darmstadt.

The uncoated comminuted glass fibers can be produced by grinding corresponding cut or chopped glass fiber strands, and are commercially available.

The uncoated comminuted ceramic fibers made of low-alkali-oxide or alkali oxide-free ceramics are in particular those made of ceramics with a purity of >98 wt. %.

It is substantial to the invention that the ceramic of the uncoated comminuted ceramic fibers has a purity of >98 wt. %.

It is also substantial to the invention that the ceramic fibers are uncoated.

The uncoated comminuted ceramic fibers are in particular those selected from the group consisting of aluminum oxide ceramic fibers, aluminum nitride ceramic fibers, silicon nitride ceramic fibers, silicon dioxide ceramic fibers, silicon carbide ceramic fibers and boron nitride ceramic fibers, each having a purity of >98 wt. %.

The uncoated comminuted ceramic fibers can have a number-average fiber length, for example, in the range of 20 to 1000 μm, preferably 40 to 600 μm, in particular 40 to 300 μm, each with a diameter, for example, in the range of 5 to 50 μm, preferably 10 to 20 μm.

The uncoated comminuted ceramic fibers can be produced by grinding corresponding cut or chopped ceramic fiber strands, and are commercially available.

The hydraulically curable inorganic cement composition according to the invention comprises in particular 5 to 15 wt. %, preferably 3 to 8 wt. % of uncoated comminuted glass fibers made of glass with a proportion of <5 wt. %, preferably <2 wt. %, particularly preferably <1 wt. % alkali oxide and/or uncoated comminuted ceramic fibers selected from the group consisting of aluminum oxide ceramic fibers, aluminum nitride ceramic fibers, silicon nitride ceramic fibers, silicon dioxide ceramic fibers, silicon carbide ceramic fibers and boron nitride ceramic fibers, each having a purity of >98 wt. %. Preferably, the hydraulically curable inorganic cement composition comprises glass fibers of said type, and the latter in particular alone, that is, without the simultaneous presence of ceramic fibers of said type.

The hydraulically curable inorganic cement composition according to the invention, which is in powder form, can be converted into an aqueous, hydraulically curable preparation which can be used as an encapsulation compound by mixing with water. The aqueous encapsulation compound can be used to produce a hydraulically cured encapsulation of an electronic component.

The hydraulically curable inorganic cement composition according to the invention comprises, in addition to said glass fibers and/or said ceramic fibers, possible non-fibrous particulate filler and possible further constituents, a hydraulically curable inorganic cement. It is a powder. The cement powder particles can, for example, have absolute particle sizes in the range of up to 1 mm. The hydraulically curable inorganic cement can, for example, be a Portland cement, high-alumina cement, magnesium oxide cement or phosphate cement known to those skilled in the art. A phosphate cement is preferred-for example, zinc phosphate cement or in particular magnesium phosphate cement. The hydraulically curable inorganic cement can, for example, constitute 2 to 95 wt. %, preferably 3 to 40 wt. % of the hydraulically curable inorganic cement composition according to the invention.

The hydraulically curable inorganic cement composition according to the invention can in particular be composed of the following constituents:
(a) 2 to 95, preferably 3 to 40 wt. % of a cement selected from the group consisting of Portland cement, high-alumina cement, magnesium oxide cement and phosphate cement,
(b) 5 to 15 wt. %, preferably 3 to 8 wt. % of uncoated comminuted glass fibers with a proportion of <5 wt. %, preferably <2 wt. %, particularly preferably <1 wt. % alkali oxide and/or uncoated comminuted ceramic fibers selected from the group consisting of aluminum oxide ceramic fibers, aluminum nitride ceramic fibers, silicon nitride ceramic fibers, silicon dioxide ceramic fibers, silicon carbide ceramic fibers and boron nitride ceramic fibers, each having a purity of >98 wt. %,
(c) 0 to 90 wt. %, preferably 40 to 80 wt. %, of at least one non-fibrous particulate filler,
(d) 0 to 30 wt. %, preferably 2 to 15 wt. %, of at least one constituent other than constituents (a) to (c). The constituents (a) to (d) add up to 100 wt. % of the hydraulically curable inorganic cement composition according to the invention; in other words, the hydraulically curable inorganic cement composition according to the invention can consist of the constituents (a) and (b) or of the constituents (a), (b) and (c) or of the constituents (a), (b) and (d) or of the constituents (a), (b), (c) and (d).

Constituent (a) is a hydraulically curable inorganic cement. It is a powder. The cement powder particles can, for example, have absolute particle sizes in the range of up to 1 mm. The hydraulically curable inorganic cement is selected from the group consisting of Portland cement, high-alumina cement, magnesium oxide cement and phosphate cement. Constituent (a) is preferably a phosphate cement, for example zinc phosphate cement or in particular magnesium phosphate cement.

The phosphate cement particularly preferred as constituent (a) can be composed of:
(a1) 10 to 90 wt. %, preferably 30 to 60 wt. %, of at least one hydrogen phosphate selected from the group consisting of mono- and dihydrogen phosphates of magnesium, calcium and aluminum, and
(a2) 90 to 10 wt. %, preferably 70 to 40 wt. %, of at least one compound selected from the group consisting of oxides, hydroxides and oxide hydrates of magnesium, calcium, iron, zinc, zirconium, lanthanum and copper. The sum of the wt. % of constituents (a1) and (a2) equals 100 wt. % of constituent (a).

Constituent (a1) is at least one substance selected from the group consisting of magnesium monohydrogen phosphate, calcium monohydrogen phosphate, aluminum monohydrogen phosphate, magnesium dihydrogen phosphate, calcium dihydrogen phosphate and aluminum dihydrogen phosphate. In other words, it is at least one hydrogen phosphate selected from the group consisting of mono- and dihydrogen phosphates of magnesium, calcium and aluminum. In particular, it is at least one hydrogen phosphate selected from the group consisting of mono- and dihydrogen phosphates of magnesium and aluminum.

Constituent (a1) is a powder with absolute particle sizes, for example, in the range of up to 1 mm.

Constituent (a2) is at least one compound selected from the group consisting of oxides, hydroxides and oxide hydrates of magnesium, calcium, iron, zinc, zirconium, lanthanum and copper, in particular at least one compound selected from the group consisting of magnesium oxide, magnesium hydroxide, zirconium oxide, zirconium oxide hydrate and zirconium hydroxide. Magnesium oxide is particularly preferred.

Constituent (a2) is a powder, for example, with absolute particle sizes in the range of up to 1 mm.

In order to avoid unnecessary length, reference is made to the above with regard to constituent (b).

The optional, but preferably present, constituent (c) is at least one non-fibrous particulate filler, which can in particular be selected from the group consisting of mono-, oligo- and polyphosphates of magnesium, calcium, barium and aluminum; calcium sulfate; barium sulfate; simple and complex silicates comprising calcium, aluminum, magnesium, iron and/or zirconium; simple and complex aluminates comprising calcium, magnesium and/or zirconium; simple and complex titanates comprising calcium, aluminum, magnesium, barium and/or zirconium; simple and complex zirconates comprising calcium, aluminum and/or magnesium; zirconium dioxide; titanium dioxide; aluminum oxide; silicon dioxide, in particular in the form of silica and quartz; silicon carbide; aluminum nitride; boron nitride and silicon nitride. A distinction is made between simple and complex silicates, aluminates, titanates and zirconates. The complex representatives are not complex compounds, but rather silicates, aluminates, titanates and zirconates with more than one type of cation, such as calcium aluminum silicate, lead zirconium titanate, etc.

Constituent (c) is a powder, for example, with absolute particle sizes in the range of up to 1 mm.

The optional constituent (d) is one or more constituents different from constituents (a) to (c), such as flow improvers, setting retarders (pot life extenders), defoamers, hydrophobizing agents, surface tension-influencing additives, wetting agents and adhesion promoters.

The hydraulically curable inorganic cement composition according to the invention and consisting in particular of the constituents (a), (b), preferably also (c) and optionally (d) can be present as a one-component powdered composition or in the form of two or more powdered components, that is, different and separate constituents (components which must be and/or are stored separately). In the case of a two- or multi-component composition, the components together comprise all constituents, that is, in particular constituents (a) and (b); and/or (a) to (c); (a) to (d); or (a), (b) and (d). The two or more components are stored separately from one another until they are used to produce an aqueous, hydraulically curable inorganic cement preparation; in this case, it may be particularly expedient to store constituents (a1) and (a2) at least substantially separately from one another.

An aqueous, hydraulically curable inorganic cement preparation can be produced from a hydraulically curable inorganic cement composition according to the invention, which can be in one-, two- or multi-component powder form, by mixing with water. In the case of a two- or multi-component system, the components can first be mixed to form a one-component hydraulically curable inorganic cement composition and then mixed with water. However, it is also possible to first mix only one, some or all of the components with water, for example to form pastes; then further mixing can take place to form the aqueous, hydraulically curable inorganic cement preparation. Such an aqueous, hydraulically curable inorganic cement preparation can be used to produce a hydraulically cured inorganic cement composition, in particular in the form of an encapsulation of an electronic component; after its application, it can cure and dry hydraulically to form a hydraulically cured inorganic cement composition in the form of a hard solid. Said hard solid body can in particular be said encapsulation of an electronic component.

An aqueous, hydraulically curable inorganic cement preparation obtainable from a hydraulically curable inorganic cement composition according to the invention by mixing with water can have a water content of, for example, 6 to 25 wt. %.

The viscosity of a freshly produced (within 5 minutes after completion) aqueous, hydraulically curable inorganic cement preparation can, for example, be in the range of 0.5 to 20 Pa·s (when determined by rotational viscometry, plate-plate measuring, plate diameter 25 mm, measuring gap 1 mm, sample temperature 20° C.).

As mentioned, the aqueous, hydraulically curable inorganic cement preparation can be used as an aqueous encapsulation compound for electronic components. For the sake of brevity, the term “aqueous encapsulation compound” will be used in the following instead of “aqueous, hydraulically curable inorganic cement preparation.”

The aqueous encapsulation compound can be used to produce a hydraulically cured encapsulation of electronic components. The production process comprises the following steps:
(1) providing an electronic component to be encapsulated,
(2) providing an aqueous encapsulation compound produced by mixing an aqueous, hydraulically curable inorganic cement composition according to the invention with water,
(3) encapsulating the electronic component provided in step (1) with the aqueous encapsulation compound provided in step (2), and
(4) hydraulically curing the aqueous encapsulation compound encapsulating the electronic component after completion of step (3).

In step (1), an electronic component to be encapsulated is provided. With regard to the term “electronic component,” reference is made to the above.

Regarding step (2), reference is made to the above.

Preferably, step (3) is carried out immediately, for example within 60 minutes, preferably within 10 minutes, after completion of step (2) or after completion of the preparation of the aqueous encapsulation compound.

In step (3), the electronic component provided in step (1) is coated with the aqueous encapsulation compound provided in step (2). Preferred application methods are casting, dipping and injection molding (transfer molding). Casting can be carried out using conventional methods known to those skilled in the art, for example by gravity, vacuum or pressure-assisted casting (compression molding). It may be expedient to enclose the electronic component to be encapsulated in half-shell molds and then fill it with the aqueous encapsulation compound. The encapsulation can be done as partial or complete encapsulation. For example, when encapsulating a semiconductor module, the encapsulation compound can partially or completely enclose electrical contacting elements connected to the semiconductor component, such as bonding wires, ribbons and/or a substrate. Partial encapsulation means that one or more of the contacting elements are incompletely encapsulated and/or one or more of the contacting elements are not encapsulated, while complete encapsulation means that all contacting elements are completely encapsulated. However, the casting can also be carried out in such a way that the encapsulation compound is formed as a “glob-top” known to those skilled in the art.

In step (4) following step (3), the aqueous encapsulation compound enveloping the electronic component is hydraulically cured. Of course, the hydraulic curing has already started from the moment the aqueous encapsulation compound has been produced, i.e., already during or after completion of step (2).

Hydraulic curing can take place under ambient conditions, for example at an ambient temperature in the range of 20 to 25° C., and can take, for example, 1 minute to 6 hours. If the duration is to be shortened, work can be carried out at higher temperatures. For example, hydraulic curing can take place at object temperatures of 30 to under 100° C. and is then completed within a few seconds to 1 hour.

Hydraulic curing is followed by drying of the encapsulation in order to remove chemically unbound water from the hydraulically cured inorganic cement composition. This can be done later in the process; however, it is also advisable to follow the hydraulic curing with forced drying for dewatering, for example for 0.5 to 6 hours at an object temperature of 80 to 300° C.; it may be advisable to go through several temperature stages. Drying can be done with vacuum assistance.

### EXAMPLES

### A) Production of Aqueous, Hydraulically Curable Inorganic Cement Preparations

Example 1 in accordance with the invention: 7 parts by weight of magnesium oxide powder, 2 parts by weight of magnesium dihydrogen phosphate powder, 4 parts by weight of 2-imidazolidinone, 6 parts by weight of uncoated aluminum borosilicate glass fibers with less than 2 wt. % alkali oxide, with a number-average fiber length of 50 μm and a diameter of 15 μm, 66 parts by weight of zirconium silicate with a maximum particle size of 100 μm and 15 parts by weight of water were mixed to form an aqueous cement preparation.

Example in accordance with the invention 2: The procedure was as in Example 1, but uncoated aluminum borosilicate glass fibers with less than 2 wt. % alkali oxide, with a number-average fiber length of 190 μm and a diameter of 15 μm, were used.

Comparative Example 3: The procedure was as in Example 1, but silane-coated aluminum borosilicate glass fibers with a number-average fiber length of 210 μm and a diameter of 15 μm were used.

### B) Evaluation of the Electrical Insulation Properties of Hydraulically Cured Inorganic Cement Compositions Produced From the Aqueous, Hydraulically Curable Inorganic Cement Preparations According to Examples 1 to 3

To evaluate the electrical insulation properties of the hydraulically cured inorganic cement compositions, five test cells were initially constructed. For this purpose, one double-sided metallized copper-aluminum oxide ceramic substrate (DCB, area 27×38 mm, thickness of the copper metallization 0.3 mm, thickness of the aluminum oxide ceramic: 0.38 mm, surrounding non-metallized aluminum oxide edge of 0.5 mm) was glued in the middle of each of five round aluminum dishes (diameter 55 mm, edge height 15 mm) using double-sided copper adhesive tape (length×width×thickness: 27±1 mm×21±1 mm×0.12 mm). Another copper adhesive tape (length×width×thickness: 50 mm×12 mm×0.11 mm) was glued in an L-shape to the upper copper foil of each of the DCB substrates (length of the glued part 10 mm, length of the bent part 40 mm).

Subsequently, 18±0.2 g of the aqueous, hydraulically curable inorganic cement preparations of Examples 1 to 3 were weighed into the aluminum dishes configured as above. It was ensured that each of the cement preparations completely covered each of the DCB substrates and had flowed to the edge of the aluminum tray. The bent part of the copper adhesive tape attached to the surface of the DCB substrate protruded vertically from the cement preparation.

The test cells were then left at 20° C. for 2 hours to allow hydraulic curing of each of the cement preparations, followed by a temperature treatment in a laboratory oven; for this purpose, the oven temperature was increased from 20° C. to 90° C. at a heating rate of 1° C./min and kept at 90° C. for 1 hour. Subsequently, the oven temperature was increased to 160° C. at a heating rate of 1° C./min and kept at 160° C. for 1 hour. Afterwards, the sample was cooled to 20° C. at a rate of 1° C./min.

To determine the electrical insulation properties, a measurement of the so-called dielectric strength was carried out on each of the 5 test cells using a TPS 652-714 measuring device from Schuster Elektronik GmbH. For this purpose, a direct current was applied using the measuring device between the aluminum shell, which was connected to the copper foil on the underside of the DCB substrate via the copper adhesive tape, and the copper adhesive tape protruding from the cement composition, which was attached to the copper foil on the top side of the DCB substrate. Initially, 100 V was applied for 1 s, which was gradually increased to 4000 V according to the indications given in Table 1. As soon as a leakage current of ≥2 mA was registered, this was interpreted as a breakdown and the test was terminated. For the test cells which were cast with the cement preparations according to the invention according to Example 1 and Example 2, the voltage could be increased up to 4000 V without any leakage current being registered. Consequently, these cement compositions exhibited good electrical insulation properties and high electrical resistance, respectively. In contrast, in test cells cast with the cement preparation according to Comparative Example 3, a leakage current of >2 mA was already detected at a voltage of 1200 V.

TABLE 1
Voltage measurement profile for determining
the breakdown voltage.

| Measurement | Voltage | Time | |
|---|---|---|---|
| point | [V] | [s] | Result |
| 1 | 100 | 1 | |
| 2 | 1000 | 1 | |
| 3 | 1200 | 1 | Breakdown in Example 3 |
| 4 | 1500 | 1 | |
| 5 | 1700 | 1 | |
| 6 | 2000 | 1 | |
| 7 | 2200 | 1 | |
| 8 | 2500 | 1 | |
| 9 | 2700 | 1 | |
| 10 | 3000 | 1 | |
| 11 | 3200 | 1 | |
| 12 | 3500 | 1 | |
| 13 | 3700 | 1 | |
| 14 | 4000 | 1 | No breakdown in Examples 1 and 2 |

1. A hydraulically hardenable inorganic cement composition comprising crushed uncoated glass fibers made of alkali oxide-poor or alkali oxide-free glass and/or crushed uncoated ceramic fibers made of alkali oxide-poor or alkali oxide-free ceramic.

2. The hydraulically hardenable inorganic cement composition according to claim 1 comprising 5 to 15 wt. % of crushed uncoated glass fibers made of glass with a proportion of <5 wt. % alkali oxide and/or crushed uncoated ceramic fibers selected from the group consisting of aluminum oxide ceramic fibers, aluminum nitride ceramic fibers, silicon nitride ceramic fibers, silicon dioxide ceramic fibers, silicon carbide ceramic fibers and boron nitride ceramic fibers each having a purity of >98 wt. %.

3. The hydraulically hardenable inorganic cement composition according to claim 1, further comprising a hydraulically hardenable inorganic cement in addition to the glass fibers and/or ceramic fibers, optional non-fibrous particulate filler and optional further components.

4. The hydraulically hardenable inorganic cement composition according to claim 3, wherein the hydraulically hardenable inorganic cement is a Portland cement, alumina cement, magnesia cement or phosphate cement.

5. The hydraulically hardenable inorganic cement composition according to claim 3, wherein the hydraulically hardenable inorganic cement accounts for 2 to 95 wt % of the hydraulically hardenable inorganic cement composition.

6. A hydraulically hardenable inorganic cement composition composed of:
(a) 2 to 95% by weight of a cement selected from the group consisting of Portland cement, alumina cement, magnesium oxide cement and phosphate cement,
(b) 5 to 15 wt. % of crushed uncoated glass fibers with a content of <5 wt. % alkali oxide and/or crushed uncoated ceramic fibers selected from the group consisting of aluminum oxide ceramic fibers, aluminum nitride ceramic fibers, silicon nitride ceramic fibers, silicon dioxide ceramic fibers, silicon carbide ceramic fibers and boron nitride ceramic fibers each having a purity of >98 wt. %,
(c) 0 to 90% by weight of at least one non-fibrous particulate filler,
(d) 0 to 30% by weight of at least one component other than components (a) to (c), wherein components (a) to (d) add up to 100% by weight.

7. The hydraulically hardenable inorganic cement composition according to claim 6, wherein component (a) is a phosphate cement composed of:
(a1) 10 to 90 wt. % of at least one hydrogen phosphate selected from the group consisting of mono- and dihydrogen phosphates of magnesium, calcium and aluminum, and
(a2) 90 to 10 wt. % of at least one compound selected from the group consisting of oxides, hydroxides and oxide hydrates of magnesium, calcium, iron, zinc, zirconium, lanthanum and copper, the sum of the weight % of components (a1) and (a2) being 100 wt. %.

8. The hydraulically hardenable inorganic cement composition according to claim 1, wherein the crushed uncoated glass fibers have a number-average fiber length in the range of 20 to 1000 pm and a diameter in the range of 5 to 50 pm.

9. The hydraulically curable inorganic cement composition according to claim 1, wherein the crushed uncoated glass fibers are selected from the group consisting of quartz glass fibers, borosilicate glass fibers, aluminosilicate glass fibers and aluminoborosilicate glass fibers.

10. The hydraulically hardenable inorganic cement composition according to claim 1, wherein the crushed uncoated ceramic fibers have a number-average fiber length in the range of 20 to 1000 pm and a diameter in the range of 5 to 50 pm.

11. The hydraulically hardenable inorganic cement composition according to claim 1 as a one-component powdered composition or in the form of two or more powdered, different and separate components.

12. An aqueous hydraulically hardenable inorganic cement preparation prepared by mixing the hydraulically hardenable inorganic cement composition according to claim 1 with water.

13. A use of an aqueous hydraulically hardenable inorganic cement preparation according to claim 12 for producing a hydraulically hardened inorganic cement composition in the form of a casing for an electronic component.

14. A method for producing a hydraulically hardened enclosure of an electronic component, comprising the steps:
(1) providing an electronic component to be encased,
(2) providing an aqueous coating mass prepared by mixing the hydraulically hardenable inorganic cement composition according to claim 1 with water,
(3) coating the electronic component provided in step (1) with the aqueous coating mass provided in step (2), and
(4) hydraulically curing the aqueous encapsulation compound enveloping the electronic component after completion of step (3).
